(19) United States
(12) Patent Application Publication
(10) Pub. No.: US 2019/0377244 A1
(43) Pub. Date: Dec. 12, 2019

(54) DASHBOARD CAMERA

(71) Applicant: SHARP KABUSHIKI KAISHA, Osaka (JP)

(72) Inventor: HIROSHI KATAYAMA, Sakai City (JP)

(21) Appl. No.: 16/394,326

(22) Filed: Apr. 25, 2019

Related U.S. Application Data
(60) Provisional application No. 62/683,632, filed on Jun. 12, 2018.

(51) Int. Cl. G03B 17/55; H04N 5/225; H05K 7/20; B60R 11/04

(52) U.S. Cl. CPC G03B 17/55; B60R 11/04; H05K 7/20436; H04N 5/2252

(57) ABSTRACT

A dashboard camera includes a lens unit, an image-capturing element that captures a subject image that is focused via the lens unit, and a circuit board on which at least the image-capturing element and an electronic component are mounted. The circuit board includes a circuit pattern on a surface facing the lens unit. A lens barrel of the lens unit includes an outer cylindrical portion that is exposed to outside of a camera housing, and a heat-dissipating plate is provided at an outer surface of the outer cylindrical portion.

### BACKGROUND OF INVENTION

### Field of Present Invention

The present invention relates to a dashboard camera that is mounted on a vehicle.

### Related Art

A dashboard camera that is mounted on a vehicle and that captures images of states in front of and behind the vehicle is required to have a wide operating temperature range. Therefore, in order to allow a dashboard camera to operate at high temperatures, a camera housing is often provided with heat-dissipating means.

For example, Japanese Unexamined Patent Application Publication No. 2017-40723 proposes making it easier to dissipate heat from a camera housing by disposing a heat-conducting material at the camera housing of a dashboard camera. As shown in FIG. 12, an existing dashboard camera 90 includes a lens assembly 92 fixed to a camera housing 91, an image-capturing element 93, and a circuit board 94 on which a peripheral circuit component thereof is mounted. An electronic component 95 on the circuit board 94 is a heating source in the camera housing 91. Therefore, a structure is formed in which a wiring pattern of the circuit board 94 and the camera housing 91 are connected to each other by a heat-conducting material 96, and heat from the electronic component 95 is dissipated via the camera housing 91.

There have existed a dashboard camera exemplified in FIG. 13 and a dashboard camera exemplified in FIG. 14. In the dashboard camera exemplified in FIG. 13, a heat-conducting material 96 is connected to a wiring pattern of a circuit board 94 on which an electronic component 95 is mounted, extends through a camera housing 91, and is led to the outside, to dissipate heat. In the dashboard camera exemplified in FIG. 14, a surface of an electronic component 95 and a camera housing 91 are connected to each other by a heat-conducting material 96 to dissipate heat via the camera housing 91. Further, there has existed a dashboard camera exemplified in FIG. 15 in which a heat-conducting material 96 connected to a surface of an electronic component 95 extends through a camera housing 91 and is led to the outside, to dissipate heat.

However, in recent years, there has been a demand for dashboard cameras to provide high pixilation and high functionality. Therefore, the quantity of heat discharged by driving an image-capturing element or a peripheral circuit component has tended to increase. Dashboard cameras are small and are shielded for ensuring weather resistance and water tightness. It is actually difficult to sufficiently dissipate heat from the inside of such small shielded camera housings.

In the existing dashboard cameras 90, heat is dissipated at the camera housing 91, and the heat may not be sufficiently dissipated. In order to further increase the heat-dissipation effect, the heat-conducting material 96 may extend through the camera housing 91 up to the outside of the camera housing 91, and a heat sink may be provided outside the camera housing 91. However, in order to provide the heat sink, a portion of the camera housing 91 through which the heat-conducting material 96 extends needs to be hermetically sealed, as a result of which a separate sealing structure is needed inside the small camera housing 91.

### SUMMARY OF INVENTION

The present invention has been made on the basis of such a background above, and it is an object of the present invention to provide a dashboard camera that can improve operability by making it possible to efficiently dissipate heat that is produced inside a camera housing to the outside of the camera housing.

(1) An embodiment of the present invention is a dashboard camera including a lens unit that includes a lens and a metal lens barrel which accommodates the lens, an image-capturing element that captures a subject image that is focused via the lens unit, a circuit board on which at least the image-capturing element and an electronic component are mounted, and a camera housing that includes an opening portion at which the lens unit is exposed with respect to a subject, and that holds the lens unit and the circuit board. The circuit board includes a circuit pattern on a surface facing the lens unit. The lens barrel includes an outer cylindrical portion that is exposed from the opening portion of the camera housing to outside of the camera housing, and a heat-dissipating plate is provided at an outer surface of the outer cylindrical portion.

(2) A certain embodiment of the present invention is a dashboard camera having, in addition to the structure of (1) above, a structure in which the heat-dissipating plate has a plate surface that is disposed in a direction of flow of air that is produced around the outer cylindrical portion.

(3) A certain embodiment of the present invention is a dashboard camera having, in addition to the structure of (1) above, a structure in which the lens barrel is connected to the circuit pattern.

(4) A certain embodiment of the present invention is a dashboard camera having, in addition to the structure of (1) above, a structure in which a heat-conducting material is connected between the lens barrel and the circuit pattern.

(5) A certain embodiment of the present invention is a dashboard camera having, in addition to the structure of (1) above, a structure in which a heat-conducting material is connected between the lens barrel and the electronic component.

(6) A certain embodiment of the present invention is a dashboard camera having, in addition to the structure of (1) above, a structure in which a heat-conducting material is connected between the camera housing and the circuit pattern.

(7) A certain embodiment of the present invention is a dashboard camera having, in addition to the structure of (1) above, a structure in which a heat-conducting material is connected between the camera housing and the electronic component.

(8) A certain embodiment of the present invention is a dashboard camera having, in addition to the structure of (2) above, a structure in which the heat-dissipating plate is disposed parallel to an image-capturing optical axis of the image-capturing element.

(9) A certain embodiment of the present invention is a dashboard camera having, in addition to the structure of (2) above, a structure in which the heat-dissipating plate is disposed in a direction orthogonal to an image-capturing optical axis of the image-capturing element.

(10) A certain embodiment of the present invention is a dashboard camera having, in addition to the structure of (2) above, a structure in which the heat-dissipating plate is disposed in a direction intersecting an image-capturing optical axis of the image-capturing element at a certain angle.

According to the dashboard camera according to the present invention, it is possible to efficiently dissipate heat that is produced at the camera housing, and to improve operability and durability.

### BRIEF DESCRIPTION OF DRAWINGS

FIG. 1 is a sectional view schematically showing a dashboard camera according Embodiment 1 of the present invention.

FIG. 2 is a plan view showing the dashboard camera of FIG. 1.

FIG. 3 is a sectional view schematically showing a dashboard camera according to Embodiment 2 of the present invention.

FIG. 4 is a sectional view schematically showing another exemplary dashboard camera according to Embodiment 2 of the present invention.

FIG. 5 is a sectional view schematically showing a dashboard camera according to Embodiment 3 of the present invention.

FIG. 6 is a sectional view schematically showing another exemplary dashboard camera according to Embodiment 3 of the present invention.

FIG. 7 is a sectional view schematically showing a dashboard camera according to Embodiment 4 of the present invention.

FIG. 8 is a sectional view schematically showing another exemplary dashboard camera according to Embodiment 4 of the present invention.

FIG. 9 is a sectional view of a lens unit, schematically showing a structure of heat-dissipating plates in a dashboard camera according to Embodiment 5 of the present invention.

FIG. 10 is a perspective view showing the lens unit of FIG. 9.

FIG. 11 is a perspective view of a lens unit, showing other exemplary heat-dissipating plates in the dashboard camera according to Embodiment 5 of the present invention.

FIG. 12 is a sectional view showing an existing dashboard camera.

FIG. 13 is a sectional view showing another exemplary existing dashboard camera.

FIG. 14 is a sectional view showing still another exemplary existing dashboard camera.

FIG. 15 is a sectional view showing still another exemplary existing dashboard camera.

### DETAILED DESCRIPTION OF INVENTION

Dashboard cameras 1 according to embodiments of the present invention are described below with reference to the drawings.

### Embodiment 1

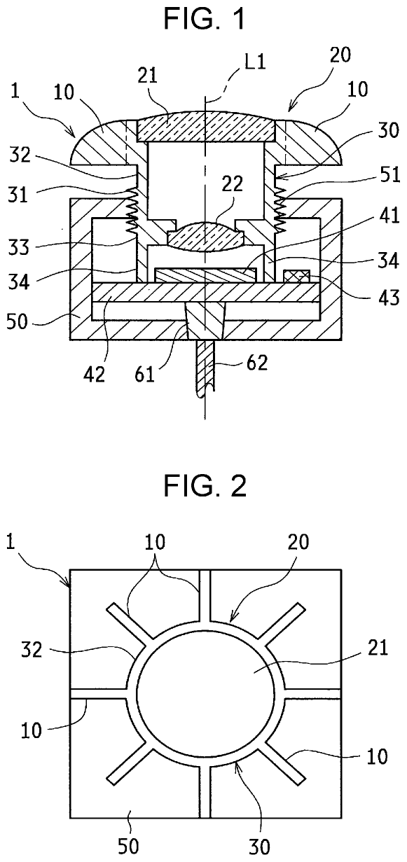

FIGS. 1 and 2 each show a dashboard camera 1 according to Embodiment 1 of the present invention. FIG. 1 is a sectional view schematically showing the dashboard camera 1, and FIG. 2 is a plan view of the dashboard camera 1.

The dashboard camera 1 is an image-capturing device including a lens unit (optical member) 20, an image-capturing element 41, a circuit board 42, and a camera housing 50. The lens unit 20 includes, for example, a lens barrel 30 and a first lens 21 and a second lens 22 accommodated inside the lens barrel 30.

The lens barrel 30 is made of a metal-based material having high thermal conductivity, such as aluminum or aluminum alloys. The first lens 21 and the second lens 22 are disposed on corresponding end portions of the lens barrel 30 in an axial direction of a central axis, and are fixed inside the lens barrel 30 via a stopping member (not shown) with an adhesive or the like. Although, in the example shown in FIG. 1, the lens unit 20 has a structure in which two lenses, that is, the first lens 21 and the second lens 22 are accommodated, the number of lenses is not limited thereto, and, thus, may be one lens or three or more lenses.

The lens unit 20 is provided as a component of the dashboard camera 1. An externally threaded portion 31 for being mounted in the camera housing 50 is provided at an outer surface of the lens barrel 30. An outer cylindrical portico 32 that is disposed so as to be exposed to the outside of the camera housing 50 is provided at the lens barrel 30 so as to be disposed above the externally threaded portion 31.

The camera housing 50 is provided with a side of the first lens 21 of the lens unit 20 exposed to a subject. the exemplified form, the camera housing 50 has an opening portion 51 to which the lens unit 20 is fixed, and an internal thread is formed at as inner periphery of the opening portion 51. The lens unit 20 is formed so that the externally threaded portion 31 of the lens barrel 30 is screwed into and mounted in the opening portion 51 to transmit light and condense the light on a surface of the image-capturing element 41.

The image-capturing element 41 is generally, for example, a CCD sensor or a CMOS sensor, and captures a subject image that is focused via the lens unit 20 and outputs a brightness signal of converted light to an image processing section. The image-capturing element 41 is, along with an electronic component 43 and a peripheral circuit component, mounted on the circuit board 42.

A connector 61 that outputs a signal is further connected to the circuit board 42. A cable 62 that transmits the signal to the outside is connected to the connector 61.

The central axis of the lens unit 20 is disposed so as to coincide with an image-capturing optical axis L1 of the image-capturing element 41. The circuit board 42 is held on an inner side of the camera housing 50 and is shielded from the outside of the camera housing 50.

Inside the camera housing 50 formed in this way, a wiring pattern or a conductive circuit pattern (not shown), such as a ground pattern electrically connected to the wiring pattern, is provided on a surface of the circuit board 42 facing the lens unit 20.

In the dashboard camera 1 according to Embodiment 1, a plurality of heat-dissipating plates 10 are provided at an outer surface of the outer cylindrical portion 32 of the lens barrel 30 making up the lens unit 20. In the form shown in FIG. 1, eight heat-dissipating plates 10 are each disposed at the outer surface of the outer cylindrical portion 32 so as to be parallel to the image-capturing optical axis L1 of the image-capturing element 41. As shown in FIG. 2, these heat-dissipating plates 10 extend uniformly and radially from the outer surface of the outer cylindrical portion 32 of the lens barrel 30.

Each heat-dissipating plate 10 is a plate member made of a metal-based material that is common to the metal-based material of the metal lens barrel 30, and its thickness and shape are not limited. For example, as shown in FIG. 1, it is desirable that each heat-dissipating plate 10 be formed so as to have a fan-shaped plate surface having a central angle of 90°, and arc-shaped portions be disposed outward. In this case, straight portions of the heat-dissipating plates 10 are mounted at the outer surface of the outer cylindrical portion 32 of the lens barrel 30, and the straight portions are disposed around the outer cylindrical portion 32 so as to be parallel to the image-capturing optical axis L1 of the image-capturing element 41. It is desirable that the plurality of heat-dissipating plates 10 and the lens barrel 30 be integrally formed by, for example, die-casting or cutting.

Alternatively, the plurality of heat-dissipating plates 10 may be formed separately from the lens barrel 30 and fixed to the outer surface of the outer cylindrical portion 32 by adhesion. In this case, the material that forms each heat-dissipating plate 10 and the metal-based material that forms the lens barrel 30 need not be the same. In addition to aluminum, each heat-dissipating plate 10 may be made of a metal-based material having a relatively high thermal conductivity, such as brass, zinc, or magnesium, or a resin-based material having high heat dissipation, such as carbon graphite.

By providing the heat-dissipating plates 10 at the outer cylindrical portion 32 of the lens barrel 30 in this way, the heat-dissipating plates 10 are provided in an arrangement form corresponding to a direction of flow of air that is produced around the outer cylindrical portion 32. Therefore, a smooth air current is formed between the heat-dissipating plates 10 without hindering the flow of air around the heat-dissipating plates 10.

An inner cylindrical portion 33 disposed inside the camera housing 50 via the opening portion 51 is provided on a side of the lens barrel 30 opposite to the outer cylindrical portion 32. The second lens 22 is held on an inner side of the inner cylindrical portion 33 and is disposed so as to face the image-capturing element 41.

The inner cylindrical portion 33 has a portion that extends up to the circuit board 42 and includes an extending portion 34. An end portion of the extending portion 34 extending from the inner cylindrical portion 33 is fixed to the circuit pattern (such as a ground pattern) of the circuit board 42. In the lens barrel 30, the inner cylindrical portion 33, the extending portion 34, the externally threaded portion 31, and the outer cylindrical portion 32 are integrally formed. Therefore, the lens barrel 30 is connected to the circuit board 42 via the extending portion 34.

In the inside of the camera housing 50, heat produced from, for example, the image-capturing element 41 and the electronic component 43 on the circuit board 42 is transmitted to the extending portion 34 of the lens barrel 30 via the circuit pattern of the circuit board 42. Further, the heat is transmitted from the extending portion 34 of the lens barrel 30 to the outer cylindrical portion 32 and is transmitted from the outer cylindrical portion 32 to the heat-dissipating plates 10. Therefore, the heat produced inside the camera housing 50 is finally transmitted to the heat-dissipating plates 10 and dissipated to the outside of the camera housing 50.

The dashboard camera 1 is mounted on a vehicle and is subjected to wind while the vehicle travels. For example, when the dashboard camera 1 is used as a camera that captures an image of a region in front of the vehicle, the first lens 21 of the lens unit 20 is set so as to face the front in a direction of travel. When the vehicle travels, an air current in the direction from the first lens 21 to the second lens 22 is produced around the outer cylindrical portion 32. That is, around the outer cylindrical portion 32, an air current is formed along the heat-dissipating plates 10 in a direction parallel to the image-capturing optical axis L1.

Therefore, around the heat-dissipating plates 10, an air current is formed in a direction of disposition of the heat-dissipating plates 10. Consequently, the heat transmitted to the heat-dissipating plates 10 is efficiently dissipated to the outside as the vehicle travels, a result of which the dissipation of heat can be promoted. Thus, even for the dashboard camera 1 whose heat quantity tends to increase, it is possible to suppress a temperature rise inside the camera housing 50 and to prevent or suppress beforehand operation failure and reduction in durability.

In the dashboard camera 1, more heat-dissipating plates 10 may be provided at the outer cylindrical portion 32 of the lens barrel 30, and, thus, the number of heat-dissipating planes 10 is not limited. The cable 62 is not necessarily limited to one being provided via the connector 61, and may be connected to the circuit board 42 by, for example, soldering.

### Embodiment 2

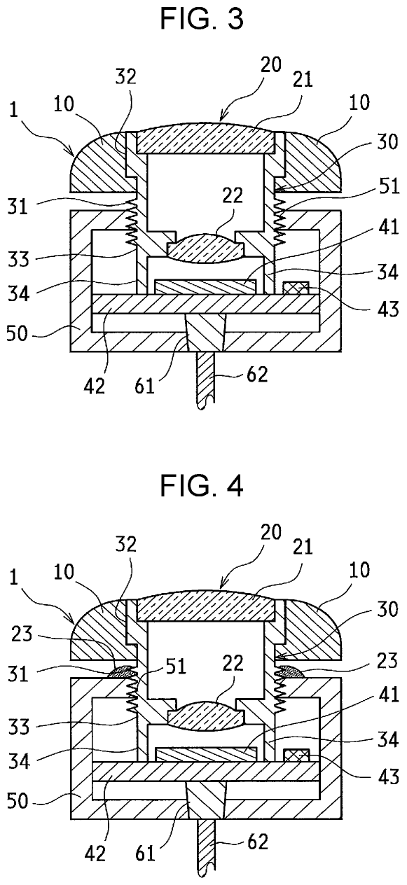

FIGS. 3 and 4 are each a sectional view schematically showing a dashboard camera 1 according to Embodiment 2 of the present invention. Since dashboard cameras 1 according to Embodiments 2 to 5 that are described below have basic structures common to the structures of Embodiment 1, the common structures are given the reference numerals used in describing Embodiment 1 and are thus not described in detail.

In the dashboard camera 1, in order to increase the heat-dissipation effect, it is desirable that the surface area of each heat-dissipating plate 10 be as large as possible. Therefore, the dashboard camera 1 according to Embodiment 2 includes heat-dissipating plates 10 having a surface area that is larger than the surface area of each heat-dissipating plate 10 indicated in Embodiment 1.

As shown in FIG. 3, the plurality of heat-dissipating plates 10 are fixed to an outer cylindrical portion 32 of a lens barrel 30 by adhesion. Each heat-dissipating plate 10 has a plate surface formed so as to be wide within a range that does not interfere with an externally threaded portion 31 of the lens barrel 30. Therefore, the heat-dissipation effect of the heat-dissipating plates 10 is further increased.

Ordinarily, when a lens unit 20 is to be mounted in a camera housing 50, the externally threaded portion 31 is adhered and fixed to an opening portion 51. Before the adhesion, by adjusting the amount of protrusion of the lens unit 20 from the opening portion 51 of the camera housing 50, the distance between an image-capturing element 41 and the lens unit 20 can be changed to adjust a focus. In contrast, when the adjustment of the focus in the dashboard camera 1 is to be made possible even after assembling the lens unit 20, as shown in FIG. 4, it is desirable that, after adjusting the focus by rotating the lens unit 20, provide a sealing material 23 around the externally threaded portion 31.

For the sealing material 23, a thermosetting sealing material or, when curing is to be performed at normal temperature, an ultraviolet curing sealing material may be used. By providing the sealing material 23 between the heat-dissipating plates 10 and the camera housing 50 and by sealing a portion around. the externally threaded portion 31, a sealing mechanism is formed at the camera housing 50 and the shielding property of the camera housing 50 is ensured.

### Embodiment 3

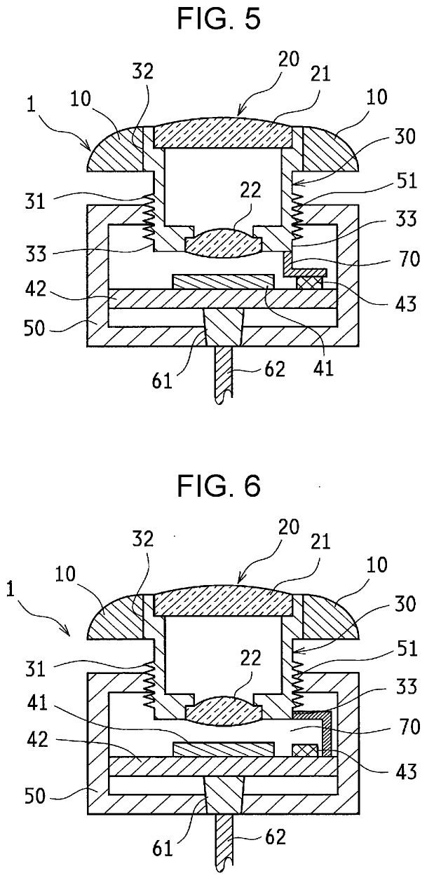

FIGS. 5 and 6 are each a sectional view schematically showing the dashboard camera 1 according to Embodiment 3 of the present invention. A distinctive feature of the dashboard camera 1 according to Embodiment 3 is a heat-conducting structure inside a camera housing 50, and the other structural members, such as heat-dissipating plates 10, are common to the structural members in Embodiment 1.

As shown in FIG. 5, in a lens unit 20 of the dashboard camera. 1, instead of the extending portion 34, a heat-conducting material 70 is disposed between a lens barrel 30 and a circuit board 42. One end portion of the heat-conducting material 70 is connected to an electronic component 43 on the circuit board 42. The other end portion of the heat-conducting material 70 is connected to an end portion of as inner cylindrical portion 33 of the lens barrel 30. For example, the heat-conducting material 70 is brought into contact with or is adhered to a surface of the electronic component 43.

For the heat-conducting material 70, it is desirable to use a material having high thermal conductivity, such as a material having a thermal conductivity of 1 W/mK or greater. Since the heat-conducting material 70 is disposed in a small space inside the camera housing 50, it is desirable that the heat-conducting material 70 be flexible and have the form of a sheet or a film that facilitates mounting. Further, it is desirable that the material have a low content of siloxane that causes contact failure. Examples of such heat-conducting material 70 include a sheet material made of a mixture of silicone polymer and a ceramic material.

Therefore, heat from the electronic component 43, which is a heating source, inside the camera housing 50 can be transmitted to the lens barrel 30 via the heat-conducting material 70 and can be efficiently dissipated from the lens barrel 30 to the outside of the camera housing 50 via the heat-dissipating plates 10.

The distance between an image-capturing element 41 and the lens unit 20 can be changed by adjusting the amount of protrusion of the lens unit 20 from an opening portion 51 of the camera housing 50. That is, the focus of the lens unit 20 can be adjusted by rotating an externally threaded portion 31 of the lens barrel 30.

As shown in FIG. 6, the heat-conducting material 70 may be formed so that one end portion of the heat-conducting material 70 is connected to, for example, a circuit pattern of the circuit board 42, and the other end portion of the heat-conducting material 70 is connected to an end portion of the inner cylindrical portion 33 of the lens barrel 30. In this case, heat that has been produced can be transmitted from the circuit board. 42 to the lens barrel 30 via the heat-conducting material 70 and can be finally dissipated from each heat-dissipating plate 10.

In this way, heat from the electronic component 43, which is a heating source, and the circuit board 42 can be efficiently and reliably transmitted to each heat-dissipating plate 10 via the heat-conducting material 70 to make it is possible to suppress a temperature rise of the camera housing 50 and to prevent or suppress beforehand operation failure and reduction in durability.

### Embodiment 4

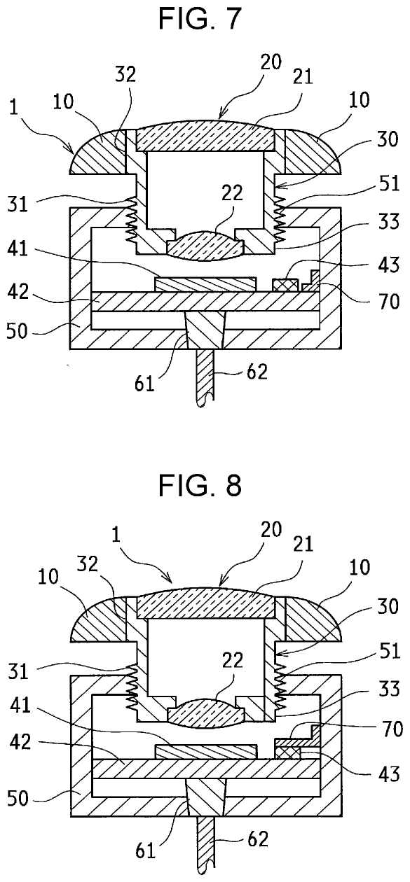

FIGS. 7 and 8 are each a sectional view schematically showing the dashboard camera 1 according to Embodiment 4 of the present invention. The dashboard camera 1 according to Embodiment 4 has a characteristic feature in its heat-conducting structure inside a camera housing 50, and the other structural members, such as heat-dissipating plates 10, are common to those in Embodiments 1 and 3.

As shown in FIG. 7, in the camera housing 50 of the dashboard camera 1, a heat-conducting material 70 is disposed between an inner wall surface of the camera housing 50 and a circuit board 42. One end portion of the heat-conducting material 70 is connected to a circuit pattern on the circuit board 42. The other end portion of the heat-conducting material 70 is connected to the inner wall surface of the camera housing 50. The circuit pattern has a terminal of an electronic component 43 connected thereto, includes, for example, a ground pattern and a pattern to which a heat-dissipating terminal of the electronic component 43 is connected, and acts to transmit heat of the electronic component 43.

In the form shown in FIG. 8, one end portion of the heat-conducting material 70 is connected to the electronic component 43 and is in contact with or is adhered to a surface of the electronic component 43. The other end portion of the heat-conducting material 70 is connected to the inner wall surface of the camera housing 50.

Therefore, heat produced by, for example, the electronic component 43 on the circuit board 42 is transmitted from the circuit pattern to the camera housing 50 via the heat-conducting material 70, or is directly transmitted from the electronic component 43 to the camera housing 50 via the heat-conducting material 70. In addition to being dissipated to the outside from the camera housing 50, the heat transmitted to the camera housing 50 is transmitted from the camera housing 50 to a lens unit 20 and is also dissipated from the heat-dissipating plates 10 of a lens barrel 30.

In such a dashboard camera 1, since the heat is efficiently dissipated from all of the camera housing 50, the lens unit 20, and the heat-dissipating plates 10, the heat-dissipation effect is further increased. By forming the camera housing 50 out of a material having high thermal conductivity, it is possible to further increase the heat-dissipation effect in the camera housing 50.

### Embodiment 5

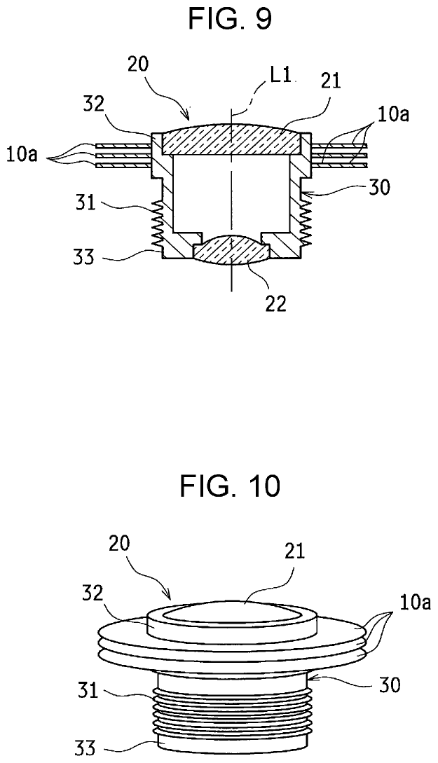

FIGS. 9 and 10 each schematically show a structure of heat-dissipating plates 10a in the dashboard camera 1 according to Embodiment 5 of the present invention. FIG. 9 is a sectional view of a lens unit 20, and FIG. 10 is a perspective view of the lens unit 20.

Depending upon the mode of mounting and the conditions for setting the dashboard camera 1 on a vehicle, the amount of wind and direction of wind with respect to the lens unit (specifically, an outer cylindrical portion 32 of a lens barrel 30) while the vehicle is traveling differ. In the present invention, the structure of the heat-dissipating plates 10 that the dashboard camera 1 includes is not limited to the structures indicated in Embodiments 1 to 4 and may be various other structures in accordance with, for example, the setting conditions of the dashboard camera 1.

As shown in FIG. 9, in the dashboard camera 1 according to Embodiment 5, the plurality of heat-dissipating plates 10a are disposed in a direction orthogonal to an image-capturing optical axis L1 of an image-capturing element 41. Each heat-dissipating plate 10a is a plate member made of a metal-based material that is the same as the metal-based material of the lens barrel 30, and its thickness and shape are not limited. For example, in the example shown in FIGS. 9 and 10, the heat-dissipating plates 10a are each formed with a disc shape that surrounds the outer cylindrical portion 32 of the lens barrel 30, and plate surfaces are disposed orthogonally to the image-capturing optical axis L1. Heat transmitted to the lens barrel 30 is transmitted to the heat-dissipating plates 10a via the outer cylindrical portion 32, and is dissipated.

When the dashboard camera 1 including such a lens unit 20 is provided in a vehicle and air current is formed around the outer cylindrical portion 32 in a direction orthogonal to the image-capturing optical axis L1 due to the vehicle traveling, since the heat-dissipating plates 10a are disposed orthogonally to the image-capturing optical axis L1, the flow of air is not prevented, as a result of which it is possible to efficiently dissipate the heat from the heat-dissipating plates 10a as the vehicle travels.

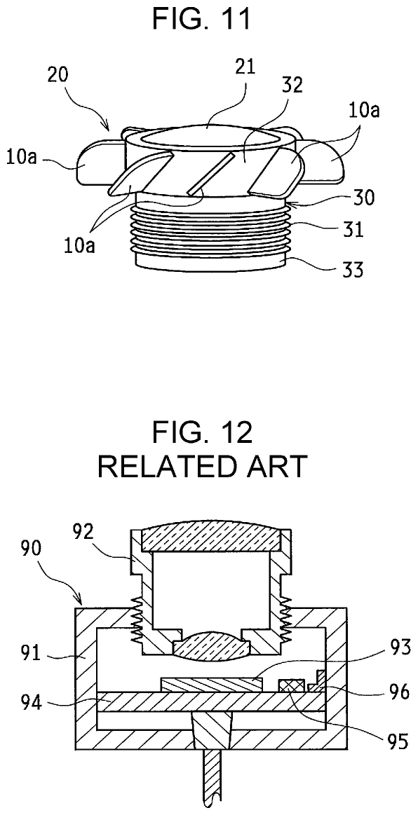

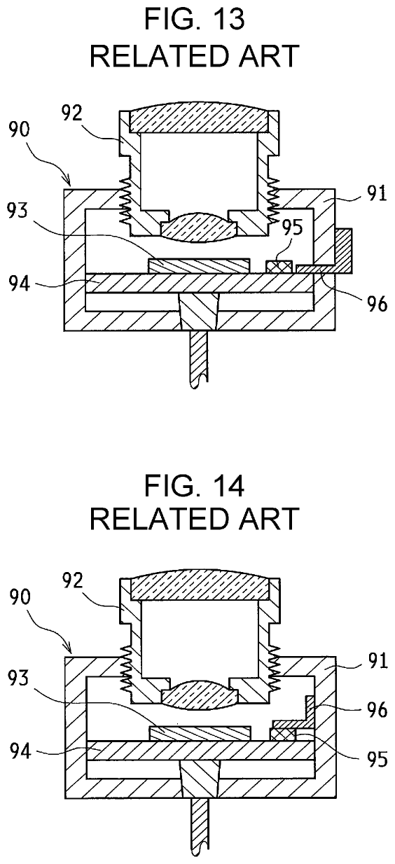

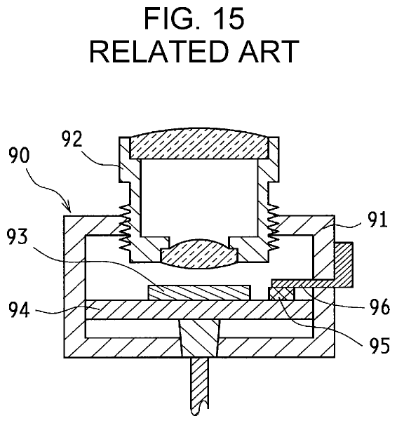

FIG. 11 shows another exemplary dashboard camera 1 according to Embodiment 5, and is a perspective view of a lens unit 20. A plurality of heat-dissipating plates 10a are tilted in a direction intersecting the image-capturing optical axis L1 at a certain angle and are uniformly disposed at an outer cylindrical portion 32. Although the shape of the heat-dissipating plates 10a and the number of heat-dissipating plates 10a are not particularly limited, for example, in the form shown in FIG. 11, the plurality of heat-dissipating plates 10a having the shape indicated in Embodiment 1 are disposed so that plate surfaces are tilted by a certain angle at a time with respect to the image-capturing optical axis L1.

The dashboard camera 1 including such a lens unit 20 is suitable for, for example, capturing an image of a region obliquely in front of and an image of a region obliquely behind a vehicle in a direction of travel of the vehicle. Since an air current in an oblique direction along the heat-dissipating plates 10a is produced around a lens barrel 30, it is possible to efficiently dissipate heat.

As described above, since, in the dashboard camera 1 according to the present invention, a temperature rise inside the camera housing 50 is suppressed, it is possible to prevent or suppress beforehand operation failure and reduction in durability. As a result, it is possible to greatly increase product stability as the dashboard camera 1.

The dashboard camera 1 according to the present invention is not limited to the structures indicated in each of the embodiments above; for example, the internal structure of the lens unit 20, the configuration related to, for example, the shape and the number of heat-dissipating plates 10, and the configuration related to, for example, the shape and the number of heat-dissipating plates 10a are not limited to those indicated in the above-described embodiments.

The present invention can be carried out in various other forms without departing from the spirit thereof and the main features thereof. Therefore, such embodiments above are merely illustrative and are not to be construed as restrictive in all respects. The scope of the present invention is defined by the claims and is not restricted in any way by the main text of the description. Further, all modifications and changes within an equivalent scope of the claims are within the scope of the present invention.

1. A dashboard camera comprising:
a lens unit that includes a lens and a metal lens barrel which accommodates the lens;
an image-capturing element that captures a subject image that is focused via the lens unit;
a circuit board on which at least the image-capturing element and an electronic component are mounted; and
a camera housing that includes an opening portion at which the lens unit is exposed with respect to a subject, and that holds the lens unit and the circuit board,
wherein the circuit board includes a circuit pattern on a surface facing the lens unit, and
wherein the lens barrel includes an outer cylindrical portion that is exposed from the opening portion of the camera housing to outside of the camera housing, and a heat-dissipating plate is provided at an outer surface of the outer cylindrical portion.

2. The dashboard camera according to claim 1, wherein the heat-dissipating plate has a plate surface that is disposed in a direction of flow of air that is produced around the outer cylindrical portion.

3. The dashboard camera according to claim 1, wherein the lens barrel is connected to the circuit pattern.

4. The dashboard camera according to claim 1, wherein a heat-conducting material is connected between the lens barrel and the circuit pattern.

5. The dashboard camera according to claim 1, wherein a heat-conducting material is connected between the lens barrel and the electronic component.

6. The dashboard camera according to claim 1, wherein a heat-conducting material is connected between the camera housing and the circuit pattern.

7. The dashboard camera according to claim 1, wherein a heat-conducting material is connected between the camera housing and the electronic component.

8. The dashboard camera according to claim 2, wherein the heat-dissipating plate is disposed parallel to an image-capturing optical axis of the image-capturing element.

9. The dashboard camera according to claim 2, wherein the heat-dissipating plate is disposed in a direction orthogonal to an image-capturing optical axis of the image-capturing element.

10. The dashboard camera according to claim 2, wherein the heat-dissipating plate is disposed in a direction intersecting an image-capturing optical axis of the image-capturing element at a certain angle.
